(19) United States
(12) Patent Application Publication
(10) Pub. No.: US 2021/0327501 A1
(43) Pub. Date: Oct. 21, 2021

(54) LOWER POWER MEMORY WRITE OPERATION

(71) Applicant: STMicroelectronics International N.V., Geneva (CH)

(72) Inventor: Kedar Janardan DHORI, Ghaziabad (IN)

(73) Assignee: STMicroelectronics International N.V., Geneva (CH)

(21) Appl. No.: 17/221,383

(22) Filed: Apr. 2, 2021

Related U.S. Application Data
(60) Provisional application No. 63/012,338, filed on Apr. 20, 2020.

(51) Int. Cl. G11C 11/419; G11C 11/412

(52) U.S. Cl. CPC G11C 11/419; G11C 11/412

(57) ABSTRACT

A static random access memory (SRAM) architecture includes a first column of SRAM cells coupled between a first bit line and a first complementary bit line, and first write circuit for the first column. The first write circuit includes a first latch receiving first input data and providing complementary outputs to the first bit line and the first complementary bit line. The first write circuit has a latchable output state driving the first bit line and first complementary bit line, and the latchable output state does not change between consecutive write operations if a state of the received first input data does not change between the consecutive write operations, but does change between the consecutive write operations if the state of the received first input data changes between the consecutive write operations.

### RELATED APPLICATION

This application claims priority to U.S. Provisional Patent Application No. 63/012,338, filed Apr. 20, 2020, the contents of which are incorporated by reference in their entirety.

### TECHNICAL FIELD

This disclosure is directed to the field of random access memory (RAM) and, in particular, to low power consumption write driving circuitry for a static random access memory (SRAM).

### BACKGROUND

A conventional SRAM cell 1 is shown in FIG. 1. The SRAM cell 1 includes an SRAM cell formed from cross coupled inverters INV1 and INV2, with n-channel pass gate transistors PG1 and PG2 selectively connecting the outputs of the cross coupled inverters INV1 and INV2 to a bit line BLT1 and a complementary bit line BLTB1, respectively. The pass gate transistors PG1 and PG2 are selectively activated by a word line signal on a word line WL.

The SRAM cell 1 also includes p-channel pre-charge transistors PCH1 and PCH2 that are selectively activated by a pre-charge signal on a pre-charge line PCHG to connect the bit line BLT1 and complementary big line BLTB1, respectively, to a supply voltage VDD. In addition, the SRAM cell 1 includes write circuitry formed by series connected n-channel write transistors WT1 and WT2 selectively connecting the bit line BLT1 to ground, and by series connected n-channel write transistors WT3 and WT4 selectively connecting the complementary bit line BLTB1 to ground. The write transistors WT1 and WT3 are selectively activated by a write signal on a write line WRITE. The write transistor WT2 is selectively activated by the output of a write driver WD (that receives data to be written as input), and the write transistor WT4 is selectively activated by the output of an inverter INV3 (that receives the output of the write driver WD as input).

It will be noted that the read circuitry for the SRAM cell 1 is not shown for simplicity.

During a write operation, the pre-charge line PCHG is driven low by the precharge signal to thereby pre-charge the bit line BLT1 and complementary bit line BLTB1 to a logic high (this is generally done at the end of previous cycle for a single port SRAM so that next cycle is ready for read or write operation cycle). This is useful because it is unknown in random access memory whether the next cycle will be a read or write operation cycle. After pre-charge, during a write operation, then the write transistors WT1 and WT3 are turned on by the write signal driving the write line WRITE to a logic high. Thereafter, the word line WL is driven high by the word line signal. When the word line WL is driven high, the output of the write driver WD controls the write transistor WT2 and the output of the inverter INV3 controls the write transistor WT4. As an example, if the data is a logic one, the write driver WD outputs a logic low, and therefore the write transistor WT2 remains off, maintaining the bit line BLT1 at a logic high due to the precharge by the precharge transistor PCH1; at the same time, the inverter INV3 outputs a logic high, and therefore the write transistor WT4 turns on to discharge the complementary bit line BLTB1 to a logic low.

This operation is repeated for each write operation. As can be appreciated, repeating this operation for each write operation results in excess power consumption (from precharge and then discharge of either BLT1 or BLTB1) where the data bit to be written is equal to the data bit already stored by the SRAM cell formed from the cross coupled inverters INV1 and INV2. Since such SRAM cells are commonly used in devices which are powered by batteries, this excess power consumption is undesirable. Therefore, further development is needed to enable the formation of SRAM cells that consume less power during write operations.

### SUMMARY

Disclosed herein is a static random access memory (SRAM) architecture including: a first column of SRAM cells coupled between a first bit line and a first complementary bit line; and data maintenance circuitry configured to preserve data states on the first bit line and the first complementary bit line between consecutive write operations if those data states do not change between those consecutive write operations.

The data maintenance circuitry may include: a first write circuit for the first column, the first write circuit having a first latch receiving first input data and providing complementary outputs to the first bit line and the first complementary bit line; wherein the first write circuit has a latchable output state driving the first bit line and first complementary bit line, and wherein the latchable output state does not change between consecutive write operations if a state of the received first input data does not change between the consecutive write operations, but does change between the consecutive write operations if the state of the received first input data changes between the consecutive write operations.

The data maintenance circuitry may include first and second buffers buffering the latchable output states driving the first bit line and first complementary bit line. Alternatively, the data maintenance circuitry may include first and second inverters inverting the latchable output states driving the first bit line and first complementary bit line.

Also disclosed herein is a static random access memory (SRAM) architecture including a plurality of memory banks. Each memory bank includes: a first SRAM cell coupled between a bank bit line and a bank complementary bit line; a second SRAM cell coupled between the bank bit line and the bank complementary bit line; and a bank write circuit including a bank latch receiving bank input data and providing complementary outputs to the bank bit line and the bank complementary bit line. The bank write circuit has a latchable output state driving the bank bit line and bank complementary bit line, the latchable output state not changing between consecutive write operations if a state of the received bank input data does not change between the consecutive write operations, but changing between the consecutive write operations if the state of the received bank input data changes between the consecutive write operations.

Also disclosed herein is a method including: latching a first data state to be written, and driving a bit line and a complementary bit line with that latched data state to write that latched data state to a first cell in a column during a first write operation; and in a second write operation immediately following the first write operation, keeping the latched data state driving the bit line and the complementary bit line if a second data state to be written to a second cell in the column is equal to the latched data state, but if the second data state is not equal to the latched data state, changing the latched data state driving the bit line and the complementary bit line to thereby write the changed latched data to the second cell.

### BRIEF DESCRIPTION OF THE DRAWINGS

FIG. 1 is a schematic diagram of a prior art SRAM cell.

FIG. 2 is a block diagram of a first SRAM cell array disclosed herein.

FIG. 3 is a schematic diagram of a given SRAM cell and given write circuitry of the first SRAM cell array of FIG. 2.

FIG. 3A is a schematic diagram of an alternative embodiment of the given SRAM cell and given write circuitry of the first SRAM cell array of FIG. 2.

FIG. 3B is a schematic diagram of a further embodiment of the given SRAM cell and given write circuitry of the first SRAM cell array of FIG. 2.

FIG. 3C is a schematic diagram of an additional embodiment of the given SRAM cell and given write circuitry of the first SRAM cell array of FIG. 2.

FIG. 4A is a block diagram of a second SRAM cell array with banking disclosed herein.

FIG. 4B is a block diagram showing input data flip flops for the write circuitry of the second SRAM cell array of FIG. 4A.

### DETAILED DESCRIPTION

The following disclosure enables a person skilled in the art to make and use the subject matter disclosed herein. The general principles described herein may be applied to embodiments and applications other than those detailed above without departing from the spirit and scope of this disclosure. This disclosure is not intended to be limited to the embodiments shown, but is to be accorded the widest scope consistent with the principles and features disclosed or suggested herein.

### A. Single Memory Bank Embodiment

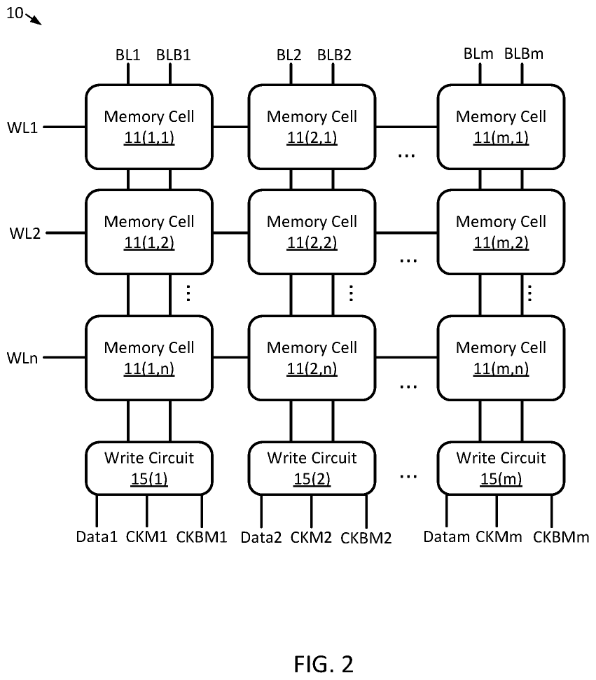

Disclosed herein with reference to FIG. 2 is an SRAM architecture 10 which consumes less power during write operations than prior art SRAM architectures.

The SRAM architecture 10 is comprised of m columns and n rows of memory cells 11, with n and m being any integers; as labeled, the memory cell in the first column and first row is 11(1,1), the memory cell in the mth column and the first row is 11(m,1), the memory cell in the first column and nth row is 11(1,n), and so on until the memory cell in the mth column and nth row is 11(m,n). Each column has an associated bit line and complementary bit line, and each row has an associated word line; as labeled, the first column is associated with bit line BL1 and complementary bit line BLB1, the second column is associated with bit line BL2 and complementary bit line BLB2, and so on until the mth column is associated with bit line BLm and complementary bit line BLBm; the first row has word line WL1 associated therewith, the second row has word line WL2 associated therewith, and so on until the nth row has word line WLn associated therewith.

A write circuit 15 is associated with each column; as labeled, the first column is associated with write circuit 15(1), the second column is associated with write circuit 15(2), and so on until the mth column is associated with write circuit 15(m). Each write circuit 15 receives input from a respective data line Data, and is clocked by a respective clock CKM and inverse clock CKBM; as labeled, the write circuit 15(1) receives input from the data line Data1 and is clocked by clock CKM1 and inverse clock CKBM1, the write circuit 15(2) receives input from the data line Data2 and is clocked by clock CKM2 and inverse clock CKBM2, and the write circuit 15(m) receives input from the data line Datam and is clocked by clock CKMm and inverse clock CKBMm.

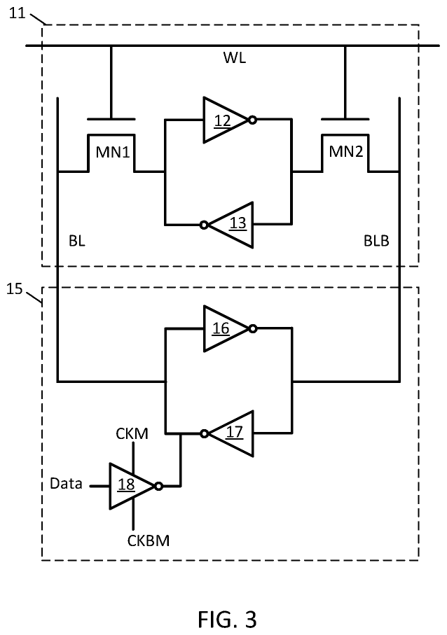

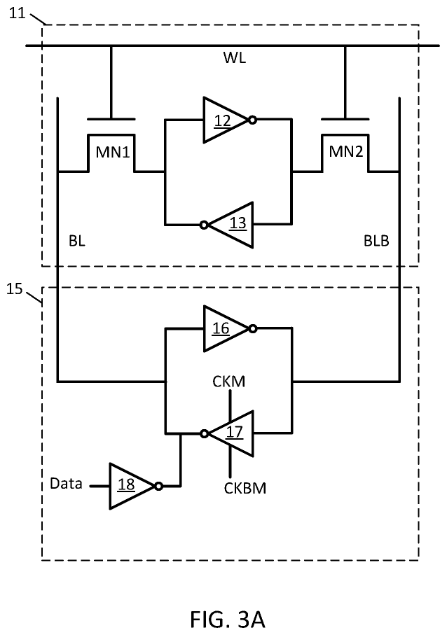

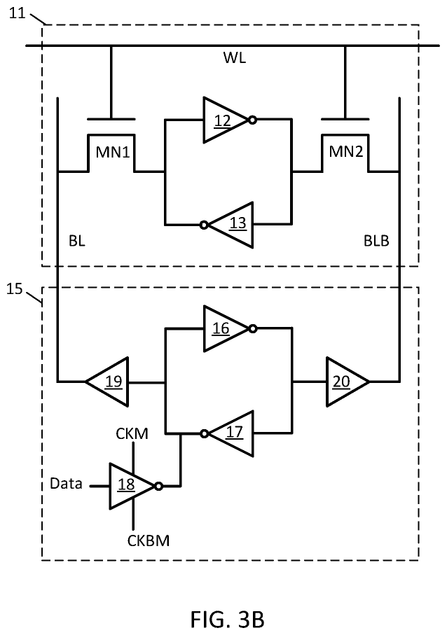

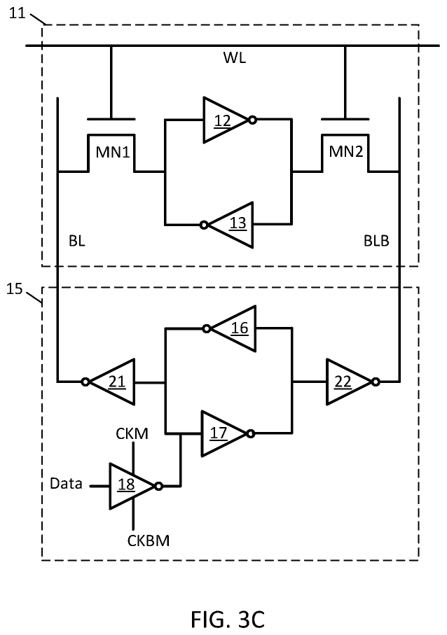

The structure and function of the SRAM cells 11 and the write circuit 15 is now described with additional reference to FIG. 3. While the SRAM cell 11(1,1) and write circuit 15(1) is illustrated in FIG. 3, it should be appreciated that each SRAM cell 11 will have the structure and function of the representative circuit 11 shown in FIG. 3 and the each write circuit 15 will have the structure and function of the representative circuit 15 shown in FIG. 3.

Each SRAM cell 11 is comprised of cross coupled inverters 12 and 13, with an n-channel pass gate transistor MN1 selectively connecting the input of the inverter 12 (and the output of the inverter 13) to the bit line BL, and with the n-channel pass gate transistor MN2 selectively connecting the input of the inverter 13 (the output of the inverter 12) to the complementary bit line BLB. The gate of the n-channel transistor MN1 is connected to the word line WL, and the gate of the n-channel transistor MN2 is also connected to the word line WL.

The write circuit 15 for the column to which the illustrate SRAM cell 11 belongs is comprised of cross coupled inverters 16 and 17 (that collectively form a latch), with the output of the inverter 17 (the input of the inverter 16) being connected to the bit line BL, and with the output of the inverter 16 (the input of the inverter 17) being connected to the complementary bit line BLB. A clocked write driver 18 (illustratively a clocked inverter) receives the data as input, is clocked by the clock signal CKM and its inverse CKBM, and provides output to the bit line BL. When not being clocked by CKM and CKBM, the output of the clocked write driver 18 is tristated. As an alternative, shown in FIG. 3A, the write driver 18 is simply an inverter, while the inverter 17 is a tri-state inverter clocked by the clock signal CKM and its inverse CKBM. As another alternative, shown in FIG. 3B, the write driver 18 is the same as in FIG. 3, but a buffer 19 receives input from the inverter 16 and provides output to the bit line BL, and a buffer 20 receives input from the inverter 17 and provides output to the complementary bit line BLB. As yet another alternative, shown in FIG. 3C, the write driver is the same as in FIG. 3, but it is the buffer 16 that provides output to the bit line BL through an inverter 21, and it is the buffer 17 that provides output to the complementary bit line BLB through an inverter 22.

For simplicity, readout circuitry is not shown for the SRAM cell, because any suitable readout circuitry may be utilized. This SRAM architecture 10, as shown, does not illustrate readout circuitry, because any suitable readout circuitry may be utilized. It should, however, be noted that while the illustrated examples apply to an SRAM with dedicated read and write ports, the illustrated write circuitry and principles may apply to any sort of memory with a dedicated write port.

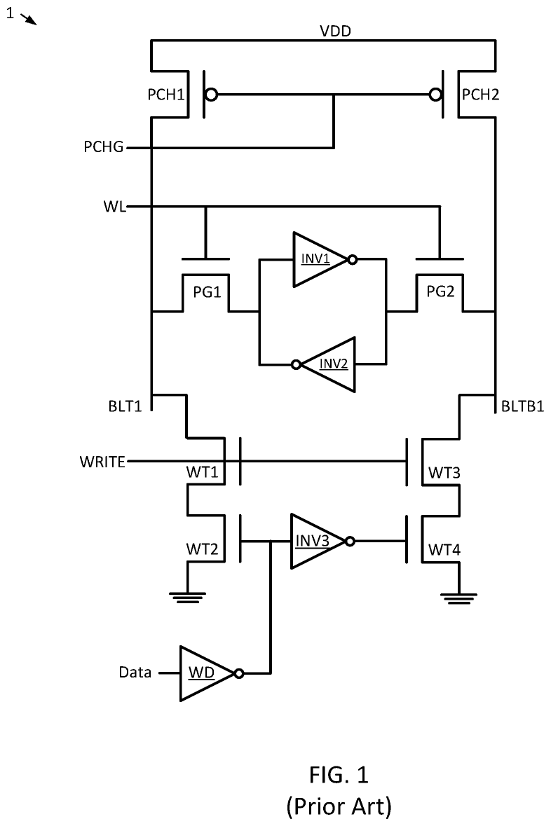

Note that traditional prior art pre-charge circuitry (see, FIG. 1) specifically for write operations is not present. Instead, the write circuit 15 operates to differentially precharge the bit lines BL and BLB to different states rather than to the same state (e.g., BL is charged to a logic high and BLB is discharged to a logic low, or BL is discharged to a logic low while BLB is charged to a logic high) or to maintain the bit lines BL and BLB at the same states they were in at the time of the immediately preceding write operation to the column to which the write circuit 15 belongs.

To effectuate this, data to be written to the selected SRAM cell 11 of the column to which the SRAM cell 11 belongs is fed to the input of the write driver 18. Note that, in a steady state, the state of the bit line BL is the same as the state of the output of the inverter 17, and the state of the complementary bit line BLB is the same as the state of the output of the inverter 16. In other words, the state of the bit lines corresponds to the state of the outputs of the latch circuit formed by the inverters 16 and 17.

When data is to be written to the selected SRAM cell 11, the write driver 18 is clocked (by the clock signal CKM1 rising to a logic high and the clock signal CKBM1 falling to a logic low). If the data to be written to the SRAM cell 11 is a logic one and the same logic value (e.g., a logic one) is already held by the cross coupled inverters 16 and 17 (meaning that the output of the inverter 17 is a logic one and the output of the inverter 16 is a logic zero), the states of the inverters 16 and 17 do not change when the write driver 18 is clocked, meaning that the outputs of the inverters 16 and 17 do not alter the current state of the bit line BL and the complementary bit line BLB.

This means that when the data to be written to the SRAM cell 11 is the same as the data written to the column to which the SRAM cell 11 belongs during an immediately preceding write operation performed on any SRAM cell of that column, little power is consumed, since the inverters 17 and 16 do not need to change the states of the bit line BL and the complementary bit line BLB. As an example, referring back to FIG. 2, if a logic one was written to SRAM cell 11(1,2) in a given write operation (performed on column 1), and then in the immediately subsequent write operation a logic one is to be written to the SRAM cell 11(1,1), power is saved because the states of the bit line BL and the complementary bit line BLB are not flipped. The conventional operations for the word line WL and the latch formed by inverters 12 and 13 would then occur, and need not be described herein.

Note that reference to an immediately subsequent write operation or a consecutive write operation refers to the case where two write operations are made to cells in the same column which occur one after another without any intervening write operation made to cells of that same column.

However, if the data to be written to the SRAM cell 11 is not the same as the data written to the column to which the SRAM cell 11 belongs during an immediately preceding write operation performed on any SRAM cell of that column, the inverters 17 and 16 will change the states of the bit line BL and the complementary bit line BLB. As an example, referring back to FIG. 2, if a logic zero was written to SRAM cell 11(1,2) in a given write operation (performed on column 1), and then in the immediately subsequent write operation a logic one is to be written to the SRAM cell 11(1,1), the states of the inverters 16 and 17 flip (such that the output of the inverter 17 rises to a logic one and the output of the inverter 16 falls to a logic zero), which has the result of changing the states of the bit line BL and the complementary bit line BLB such that the bit line BL is driven to a logic high, and the complementary bit line BLB is driven to a logic low. Once sufficient time has passed for the bit line BL and the complementary bit line BLB to settle at their new values (e.g., BL being a logic one and BLB being a logic zero), the write operation proceeds with a logic high being applied to the word line WL of the row to which the SRAM cell 11 belongs, turning on the pass gate transistors MN1 and MN2, thereby allowing the output of the inverters 17 and 16 to flip the states of the inverters 12 and 13 if the inverters 12 and 13 store opposite logic states to the inverters 17 and 16.

As another example, if a logic one was written to the SRAM cell 11(1,2), and then in the immediately subsequent write operation (performed on column 1) a logic zero is to be written to the SRAM cell 11(1,1), the states of the inverters 16 and 17 flip (such that the output of the inverter 16 rises to a logic one and the output of the inverter 17 falls to a logic zero), which has the result of changing the states of the bit line BL and the complementary bit line BLB. Thus, if the data to be written to the SRAM cell 11 is a logic zero, the bit line BL is driven to a logic low, and the complementary bit line BLB is driven to a logic high. Once sufficient time has passed for the bit line BL and the complementary bit line BLB to settle at their new values (e.g., BL being a logic zero and BLB being a logic high), the write operation proceeds with a logic high being applied to the word line WL, turning on the pass gate transistors MN1 and MN2, thereby allowing the output of the inverters 17 and 16 to flip the states of the inverters 12 and 13.

### B. Dual Memory Bank Embodiment

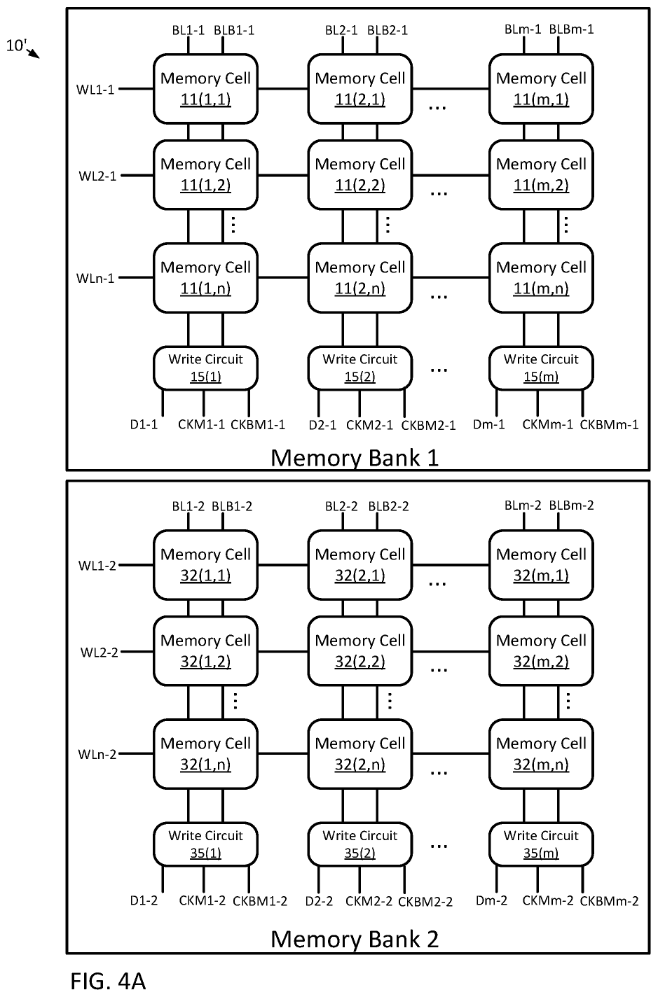

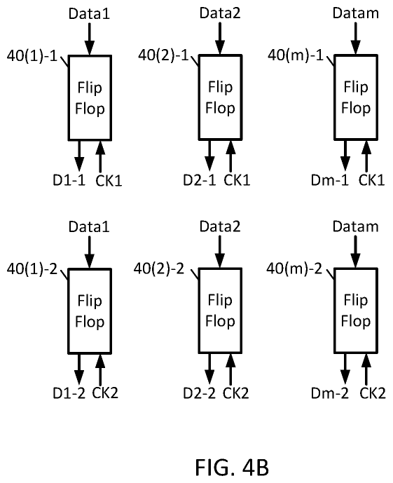

Shown in FIG. 4A is an embodiment of the SRAM architecture 10′ in which there are two memory banks that may be individually selected to provide for power savings (e.g., by one bank being activated while the other bank is deactivated).

The first memory bank is comprised of m columns and n rows of memory cells 11, with m and n being any integers; as labeled, the memory cell in the first column and first row is 11(1,1), the memory cell in the mth column and the first row is 11(m,1), the memory cell in the first column and nth row is 11(1,n), and so on until the memory cell in the mth column and nth row is 11(m,n). Each column has an associated bit line and complementary bit line, and each row has an associated word line; as labeled, the first column is associated with bit line BL1-1 and complementary bit line BLB1-1, the second column is associated with bit line BL2-1 and complementary bit line BLB2-1, and so on until the mth column is associated with bit line BLm-1 and complementary bit line BLBm-1; the first row has word line WL1-1 associated therewith, the second row has word line WL2-1 associated therewith, and so on until the nth row has word line WLn-1 associated therewith.

Write circuit 15 is associated with each column of the first memory bank; as labeled, the first column is associated with write circuit 15(1), the second column is associated with write circuit 15(2), and so on until the mth column is associated with write circuit 15(m). Each write circuit block 15 receives input from a respective data line D, and is clocked by a respective clock CKM and inverse clock CKBM; as labeled, the write circuit 15(1) receives input from the data line D1-1 and is clocked by clock CKM1-1 and inverse clock CKBM1-1, the write circuit 15(2) receives input from the data line D2-1 and is clocked by clock CKM2-1 and inverse clock CKBM2-1, and the write circuit 15(m) receives input from the data line Dm-1 and is clocked by clock CKMm-1 and inverse clock CKBMm-1.

The data line D1-1, D2-1, Dm-1 for each column of the first memory bank is driven by a flip flop 40-1, as shown in FIG. 4B. The data line D1-1 is driven by the output of the flip flop 40(1)-1, and the flip flop 40(1)-1 is connected to the data line Data1 to receive input data and is clocked by the clock signal CK1. The data line D2-1 is driven by the output of the flip flop 40(2)-1, and the flip flop 40(2)-1 is connected to the data line Data2 to receive input data and is clocked by the clock signal CK1. The data line Dm-1 is driven by the output of the flip flop 40(m)-1, and the flip flop 40(m)-1 is connected to the data line Datam to receive input data and is clocked by the clock signal CK1.

The second memory bank is comprised of m columns and n rows of memory cells 32 that are identical to the memory cells 11 in structure and function as shown in FIG. 3; as labeled, the memory cell in the first column and first row is 32(1,1), the memory cell in the mth column and the first row is 32(m,1), the memory cell in the first column and nth row is 32(1,n), and so on until the memory cell in the mth column and nth row is 32(m,n). Each column has an associated bit line and complementary bit line, and each row has an associated word line; as labeled, the first column is associated with bit line BL1-2 and complementary bit line BLB1-2, the second column is associated with bit line BL2-2 and complementary bit line BLB2-2, and so on until the mth column is associated with bit line BLm-2 and complementary bit line BLBm-2; the first row has word line WL1-2 associated therewith, the second row has word line WL2-2 associated therewith, and so on until the nth row has word line WLn-2 associated therewith.

Write circuit 35 is associated with each column of the second memory bank; as labeled, the first column is associated with write circuit 35(1), the second column is associated with write circuit 35(2), and so on until the mth column is associated with write circuit 35(m). Each write circuit block 35 receives input from a respective data line D, and is clocked by a respective clock CKM and inverse clock CKBM; as labeled, the write circuit 35(1) receives input from the data line D1-2 and is clocked by clock CKM1-2 and inverse clock CKBM1-2, the write circuit 35(2) receives input from the data line D2-2 and is clocked by clock CKM2-2 and inverse clock CKBM2-2, and the write circuit 35(m) receives input from the data line Dm-2 and is clocked by clock CKMm-2 and inverse clock CKBMm-2.

The data line D1-2, D2-2, Dm-2 for each column of the second memory bank is driven by a flip flop 40-2, as also shown in FIG. 4B. The data line D1-2 is driven by the output of the flip flop 40(1)-2, and the flip flop 40(1)-2 is connected to the data line Data1 to receive input data and is clocked by the clock signal CK2. The data line D2-2 is driven by the output of the flip flop 40(2)-2, and the flip flop 40(2)-2 is connected to the data line Data2 to receive input data and is clocked by the clock signal CK2. The data line Dm-2 is driven by the output of the flip flop 40(m)-2, and the flip flop 40(m)-2 is connected to the data line Datam to receive input data and is clocked by the clock signal CK2.

The operation of the individual SRAM cells 11 of each memory bank is the same as described above. The clock signal CKM1-1, CKBM1-1, CKM2-1, CKBM2-1, CKMm-1, CKBMm-1, CKM1-2, CKBM1-2, CKM2-2, CKBM2-2, CKMm-2, and CKBMm-2 are based upon the clock signal CK. Therefore, the purpose of the flip flops 40 is to ensure that the output on the data lines D1-1, D2-1, Dm-1, D1-2, D2-2, Dm-2 is stable at the beginning of the write operation. The clock scheme shown in this disclosure is solely for the purposes of illustration, and it will be understood by those of skill in the art that various clocking schemes and combinations can be used, for example based on bank by bank operation or multiplexing, as is desired by the specific SRAM design.

While the disclosure has been described with respect to a limited number of embodiments, those skilled in the art, having benefit of this disclosure, will appreciate that other embodiments can be envisioned that do not depart from the scope of the disclosure as disclosed herein. Accordingly, the scope of the disclosure shall be limited only by the attached claims.

1. A static random access memory (SRAM) architecture, comprising:
a first column of SRAM cells coupled between a first bit line and a first complementary bit line; and
data maintenance circuitry configured to preserve data states on the first bit line and the first complementary bit line between consecutive write operations if those data states do not change between those consecutive write operations.

2. The SRAM architecture of claim 1, wherein the data maintenance circuitry comprises:
a first write circuit for the first column of SRAM cells, the first write circuit comprising a first latch receiving a first input data and providing complementary outputs to the first bit line and the first complementary bit line; and
wherein the first write circuit has a latchable output state driving the first bit line and first complementary bit line, wherein the latchable output state does not change between consecutive write operations if a state of the received first input data does not change between the consecutive write operations, but wherein the latchable output state does change between the consecutive write operations if the state of the received first input data changes between the consecutive write operations.

3. The SRAM architecture of claim 2, wherein the data maintenance circuitry comprises first and second buffers buffering the latchable output states driving, respectively, the first bit line and first complementary bit line.

4. The SRAM architecture of claim 3, wherein the data maintenance circuitry comprises first and second inverters inverting the latchable output states driving, respectively, the first bit line and first complementary bit line.

5. A static random access memory (SRAM) architecture, comprising:
a first column of SRAM cells coupled between a first bit line and a first complementary bit line; and
a first write circuit for the first column of SRAM cells, the first write circuit comprising a first latch receiving first input data and providing complementary outputs to the first bit line and the first complementary bit line;
wherein the first write circuit has a latchable output state driving the first bit line and first complementary bit line, wherein the latchable output state does not change between consecutive write operations if a state of the received first input data does not change between the consecutive write operations, but wherein the latchable output state does change between the consecutive write operations if the state of the received first input data changes between the consecutive write operations.

6. The SRAM architecture of claim 5, further comprising a first clocked inverter having an input receiving first data and having an output driving the first input data to an input of the first latch.

7. The SRAM architecture of claim 6, wherein the first latch comprises first and second inverters that are cross coupled, with an input of the first inverter being coupled to the first bit line and an output of the first inverter being coupled to the first complementary bit line, and with an input of the second inverter being coupled to the first complementary bit line and an output of the second inverter being coupled to the first bit line; and wherein the output of the first clocked inverter is tristated other than when being clocked.

8. The SRAM architecture of claim 7, wherein a first SRAM cell of the first column of SRAM cells is comprised of:
third and fourth inverters that are cross coupled, with an output of the fourth inverter coupled to the input of the third inverter, and with an output of the third inverter coupled to the input of the fourth inverter; and
first and second pass gate transistors, with the first pass gate transistor coupled between the first bit line and the input of the third inverter, and with the second pass gate transistor coupled between the first complementary bit line and the input of the fourth inverter, and with the first and second pass gate transistors being selectively turned on and off by a first word line signal.

9. The SRAM architecture of claim 8, wherein the first clocked inverter is clocked prior to the first word line signal turning on the first and second pass gate transistors.

10. The SRAM architecture of claim 6, wherein the first write circuit includes a first flip flop receiving first memory input data and providing the first data to the first clocked inverter.

11. The SRAM architecture of claim 5, further comprising:
a second column of SRAM cells coupled between a second bit line and a second complementary bit line; and
a second write circuit for the second column of SRAM cells, the second write circuit comprising a second latch receiving second input data and providing complementary outputs to the second bit line and the second complementary bit line;
wherein the second write circuit has a latchable output state driving the second bit line and second complementary bit line, wherein the latchable output state of the second write circuit does not change between consecutive write operations if a state of the received second input data does not change between the consecutive write operations, but wherein the latchable output state does change between the consecutive write operations if the state of the received second input data changes between the consecutive write operations.

12. The SRAM architecture of claim 11, further comprising a second clocked inverter having an input receiving second data and having an output driving the second input data to an input of the second latch; wherein the second latch comprises first and second inverters that are cross coupled, with an input of the first inverter of the second latch being coupled to the second bit line and an output of the first inverter of the second latch being coupled to the second complementary bit line, and with an input of the second inverter of the second latch being coupled to the second complementary bit line and an output of the second inverter of the second latch being coupled to the second bit line; and wherein the output of the second clocked inverter is tristated other than when being clocked.

13. The SRAM architecture of claim 1, wherein the first bit line is a dedicated write bit line, and wherein the first complementary bit line is a dedicated complementary write bit line.

14. A static random access memory (SRAM) architecture, comprising:
a plurality of memory banks, each memory bank comprising:
a first SRAM cell coupled between a bank bit line and a bank complementary bit line;
a second SRAM cell coupled between the bank bit line and the bank complementary bit line; and
a bank write circuit comprising a bank latch receiving bank input data and providing complementary outputs to the bank bit line and the bank complementary bit line;
wherein the bank write circuit has a latchable output state driving the bank bit line and bank complementary bit line, the latchable output state not changing between consecutive write operations if a state of the received bank input data does not change between the consecutive write operations, but the latchable output state changing between the consecutive write operations if the state of the received bank input data changes between the consecutive write operations.

15. The SRAM architecture of claim 14, wherein each memory bank further comprises a clocked inverter having an input receiving bank data and having an output driving the bank input data to an input of the bank latch.

16. The SRAM architecture of claim 15, wherein the bank latch comprises first and second inverters that are cross coupled, with an input of the first inverter being coupled to the bank bit line and an output of the first inverter being coupled to the bank complementary bit line, and with an input of the second inverter being coupled to the bank complementary bit line and an output of the second inverter being coupled to the bank bit line; wherein the output of the clocked inverter is tristated other than when being clocked.

17. The SRAM architecture of claim 16, wherein the first SRAM cell is comprised of:
third and fourth inverters that are cross coupled, with an output of the fourth inverter coupled to the input of the third inverter, and with an output of the third inverter coupled to the input of the fourth inverter; and
first and second pass gate transistors, with the first pass gate transistor coupled between the bank bit line and the input of the third inverter, and with the second pass gate transistor coupled between the complementary bank bit line and the input of the fourth inverter, and with the first and second pass gate transistors being selectively turned on and off by a word line signal.

18. The SRAM architecture of claim 17, wherein the clocked inverter is clocked prior to the word line signal turning on the first and second pass gate transistors of the first SRAM cell.

19. The SRAM architecture of claim 15, wherein the bank write circuit includes a first flip flop receiving bank memory input data and providing the bank data to the clocked inverter.

20. A static random access memory (SRAM) architecture, comprising:
a first memory bank comprising:
a first SRAM cell coupled between a first bank bit line and a first bank complementary bit line;
a second SRAM cell coupled between the first bank bit line and the first bank complementary bit line; and
a first bank write circuit comprising a first latch receiving first bank input data and providing complementary outputs to the first bank bit line and the first bank complementary bit line;
wherein the first bank write circuit has a latchable output state driving the first bank bit line and first bank complementary bit line, the latchable output state not changing between consecutive write operations if a state of the received first bank input data does not change between the consecutive write operations, but changing between the consecutive write operations if the state of the received first bank input data changes between the consecutive write operations;
a second memory bank comprising:
a third SRAM cell coupled between a second bank bit line and a second bank complementary bit line;
a fourth SRAM cell coupled between the second bank bit line and the second bank complementary bit line; and
a second bank write circuit comprising a second latch receiving second bank input data and providing complementary outputs to the second bank bit line and the second bank complementary bit line;
wherein the second bank write circuit has a latchable output state driving the second bank bit line and second bank complementary bit line, the latchable output state not changing between consecutive write operations if a state of the received second bank input data does not change between the consecutive write operations, but changing between the consecutive write operations if the state of the received second bank input data changes between the consecutive write operations.

21. The SRAM architecture of claim 20, wherein the first memory bank further comprises a first clocked inverter having an input receiving first bank data and having an output driving the first bank input data to an input of the first latch; and wherein the second memory bank further comprises a second clocked inverter having an input receiving second bank data and having an output driving the second bank input data to an input of the second latch.

22. The SRAM architecture of claim 21, wherein the first latch comprises first and second inverters that are cross coupled, with an input of the first inverter being coupled to the first bank bit line and an output of the first inverter being coupled to the first bank complementary bit line, and with an input of the second inverter being coupled to the first bank complementary bit line and an output of the second inverter being coupled to the first bank bit line; wherein the output of the first clocked inverter is tristated other than when being clocked; wherein the second latch comprises first and second inverters that are cross coupled, with an input of the first inverter of the second latch being coupled to the second bank bit line and an output of the first inverter of the second latch being coupled to the second bank complementary bit line, and with an input of the second inverter of the second latch being coupled to the second bank complementary bit line and an output of the second inverter of the second latch being coupled to the second bank bit line; and wherein the output of the second clocked inverter is tristated other than when being clocked

23. The SRAM architecture of claim 22,
wherein the first SRAM cell is comprised of:
third and fourth inverters that are cross coupled, with an output of the fourth inverter coupled to the input of the third inverter, and with an output of the third inverter coupled to the input of the fourth inverter; and
first and second pass gate transistors, with the first pass gate transistor coupled between the first bank bit line and the input of the third inverter, and with the second pass gate transistor coupled between the first complementary bank bit line and the input of the fourth inverter, and with the first and second pass gate transistors being selectively turned on and off by a first word line signal;
wherein the third SRAM cell is comprised of:
third and fourth inverters that are cross coupled, with an output of the fourth inverter of the third SRAM cell coupled to the input of the third inverter of the third SRAM cell, and with an output of the third inverter of the third SRAM cell coupled to the input of the fourth inverter of the third SRAM cell; and
first and second pass gate transistors, with the first pass gate transistor of the third SRAM cell coupled between the second bank bit line and the input of the third inverter of the third SRAM cell, and with the second pass gate transistor of the third SRAM cell coupled between the second complementary bank bit line and the input of the fourth inverter of the third SRAM cell, and with the first and second pass gate transistors of the third SRAM cell being selectively turned on and off by a second word line signal;

24. The SRAM architecture of claim 23, wherein the first clocked inverter is clocked prior to the first word line signal turning on the first and second pass gate transistors of the first SRAM cell; and wherein the second clocked inverter is clocked prior to the second word line signal turning on the first and second pass gate transistors of the third SRAM cell.

25. The SRAM architecture of claim 21, wherein the first write circuit includes a first flip flop receiving first bank memory input data and providing the first bank data to the first clocked inverter; and wherein the second write circuit includes a second flip flop receiving second bank memory input data and providing the second bank data to the second clocked inverter.

26. A method, comprising:
latching a first data state to be written;
driving a bit line and a complementary bit line with that latched data state to write that latched data state to a first cell in a column, during a first write operation; and
in a second write operation immediately following the first write operation, keeping the latched data state driving the bit line and the complementary bit line if a second data state to be written to a second cell in the column is equal to the latched data state, but if the second data state is not equal to the latched data state, changing the latched data state driving the bit line and the complementary bit line to thereby write the changed latched data to the second cell.

27. The method of claim 26, further comprising passing the first data state to be written through a clocked inverter when the clocked inverter is clocked, and otherwise tristating the clocked inverter.

28. The method of claim 27, further comprising passing first data as the first data state, through a flip flop, to the clocked inverter when the flip flop is clocked.

29. A static random access memory (SRAM) architecture, comprising:
a plurality of memory banks, each memory bank comprising:
a first SRAM cell coupled between a bank bit line and a bank complementary bit line;
a second SRAM cell coupled between the bank bit line and the bank complementary bit line; and
a bank write circuit comprising a bank latch receiving bank input data and providing complementary outputs to the bank bit line and the bank complementary bit line;
wherein the bank write circuit has a latchable output state driving the bank bit line and bank complementary bit line, the latchable output state not changing between consecutive write operations when a state of the received bank input data does not change between the consecutive write operations.

30. The SRAM architecture of claim 29, wherein each memory bank further comprises a clocked inverter having an input receiving bank data and having an output driving the bank input data to an input of the bank latch.

31. The SRAM architecture of claim 30, wherein the bank latch comprises first and second inverters that are cross coupled; and wherein the output of the clocked inverter is tristated other than when being clocked.

32. The SRAM architecture of claim 31, wherein the first SRAM cell is comprised of:
third and fourth inverters that are cross coupled, with an output of the fourth inverter coupled to the input of the third inverter, and with an output of the third inverter coupled to the input of the fourth inverter; and
first and second pass gate transistors, with the first pass gate transistor coupled between the bank bit line and the input of the third inverter, and with the second pass gate transistor coupled between the complementary bank bit line and the input of the fourth inverter, and with the first and second pass gate transistors being selectively turned on and off by a word line signal.

33. The SRAM architecture of claim 32, wherein the clocked inverter is clocked prior to the word line signal turning on the first and second pass gate transistors of the first SRAM cell.

34. The SRAM architecture of claim 30, wherein the bank write circuit includes a first flip flop receiving bank memory input data and providing the bank data to the clocked inverter.
